(19) United States
(12) Patent Application Publication
(10) Pub. No.: US 2003/0179622 A1
(43) Pub. Date: Sep. 25, 2003

(54) Dual modulation tuning in systems that exhibit self-disturbance effects

(76) Inventors: Ehud Langberg, Wayside, NJ (US); Peter Kleewein, Eatontown, NJ (US); WingIp Tam, Monmouth Beach, NJ (US); Feng Ouyang, Holmdel, NJ (US); Laurent Pierrugues, Rahway, NJ (US); Oliver Moreno, Eatontown, NJ (US); Patrick Duvaut, Belford, NJ (US)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/371,697

(22) Filed: Feb. 21, 2003

Related U.S. Application Data
(63) Continuation-in-part of application No. 10/315,743, filed on Dec. 10, 2002.
(63) Continuation-in-part of application No. 10/316,081, filed on Dec. 10, 2002.
(63) Continuation-in-part of application No. 10/316,155, filed on Dec. 10, 2002.
(60) Provisional application No. 60/358,644, filed on Feb. 21, 2002.

(51) Int. Cl. G11C 7/00

(52) U.S. Cl. 365/200

(57) ABSTRACT

This invention provides approaches for dual-modulation tuning in systems that exhibit self-disturbance. In one embodiment, a dual-bit-mapping scheme is used so that system parameters are set according to one bit-mapping scheme when self-disturbance is present and to another bit-mapping scheme when self-disturbance is not present in the system. Self-disturbance may include signals that arise from echoes or near-end cross-talk (NEXT).

### CROSS-REFERENCE TO RELATED APPLICATION

The present application claims the benefit of U.S. provisional patent application serial No. 60/358,644, filed on Feb. 21, 2002, entitled “Dual Modulation Tuning for Self-disturbance,” which is incorporated by reference herein in its entirety.

The present application is a continuation-in-part of U.S. patent application Ser. Nos. 10/315,743, 10/316,081, and 10/316,155, all of which were filed on Dec. 10, 2002. These applications are incorporated by reference as if set forth in their entireties.

### FIELD OF THE INVENTION

The present invention generally relates to data communication. More specifically, the present invention relates to dual-modulation tuning in systems that exhibit self-disturbance effects.

### BACKGROUND

Industries related to modern communication systems have seen a tremendous growth due to the increasing popularity of the Internet. These communication systems include digital subscriber line (DSL) systems. Certain DSL systems manifest self-disturbance effects when upstream data communication and downstream data communication take place in overlapping bandwidths. Echo cancellation techniques have been used in order to reduce the self-disturbance effects. However, these techniques typically result in sub-optimal system settings. Therefore, other approaches for reducing self-disturbance effects are desired in the industry.

### SUMMARY

The present invention provides dual-modulation tuning in systems that exhibit self-disturbance.

Briefly described, in architecture, one embodiment of the system comprises a processor and a transmitter. The processor is adapted to determine presence or absence of self-disturbance in a communication system, and to set system parameters in response to determining whether or not self-disturbance is present in the communication system. The transmitter is adapted to transmit data using the system parameters set by the processor.

The present invention can also be viewed as providing methods for dual-modulation tuning in systems that exhibit self-disturbance. In this regard, one embodiment of such a method can be broadly summarized as having the steps of determining presence or absence of self-disturbance in a system, and setting system parameters to different data-transmission modes in response to determining whether or not self-disturbance is present in the system. In this regard, the method is applicable to systems that are capable of at least two data-transmission modes.

Other systems, methods, features, and advantages of the present invention will be or become apparent to one with skill in the art upon examination of the following drawings and detailed description. It is intended that all such additional systems, methods, features, and advantages be included within this description, be within the scope of the present invention, and be protected by the accompanying claims.

### BRIEF DESCRIPTION OF THE DRAWINGS

Many aspects of the invention can be better understood with reference to the following drawings. The components in the drawings are not necessarily to scale, emphasis instead being placed upon clearly illustrating the principles of the present invention. Moreover, in the drawings, like reference numerals designate corresponding parts throughout the several views.

FIG. 1 is a block diagram showing a non-limiting example of a digital communication system as an asymmetric digital subscriber line (ADSL) system.

FIG. 2 is a graph showing an example of time-division multiplexing.

FIG. 3 is a graph showing an example of frequency-division multiplexing.

FIG. 4 is a graph showing full-bandwidth overlap of upstream and downstream signals in a particular frequency range for an ADSL modem operating in an echo-cancellation mode when self-disturbance effects are present.

FIG. 5 is a block diagram showing the ADSL modem of FIG. 1 in greater detail.

FIG. 6 is a block diagram showing the encoder and automatic gain scaler of FIG. 5 in greater detail.

FIG. 7A is a graph showing partial-bandwidth overlap of upstream and downstream signals in a particular frequency range for an ADSL modem exhibiting self-disturbance effects.

FIG. 7B is a graph showing dual bit-mapping of data for systems exhibiting self-disturbance effects when there is a partial-bandwidth overlap of upstream and downstream signals.

FIG. 8 is a flowchart showing one embodiment of a method that employs dual-modulation tuning in systems that exhibit self-disturbance effects.

FIG. 9 is a flowchart showing another embodiment of a method that employs dual-modulation tuning in systems that exhibit self-disturbance effects.

### DETAILED DESCRIPTION OF THE PREFERRED EMBODIMENTS

Having summarized various aspects of the present invention, reference is now made in detail to the description of the embodiments as illustrated in the drawings. While the several embodiments are described in connection with these drawings, there is no intent to limit the invention to the embodiment or embodiments disclosed herein. On the contrary, the intent is to cover all alternatives, modifications, and equivalents included within the spirit and scope of the invention as defined by the appended claims.

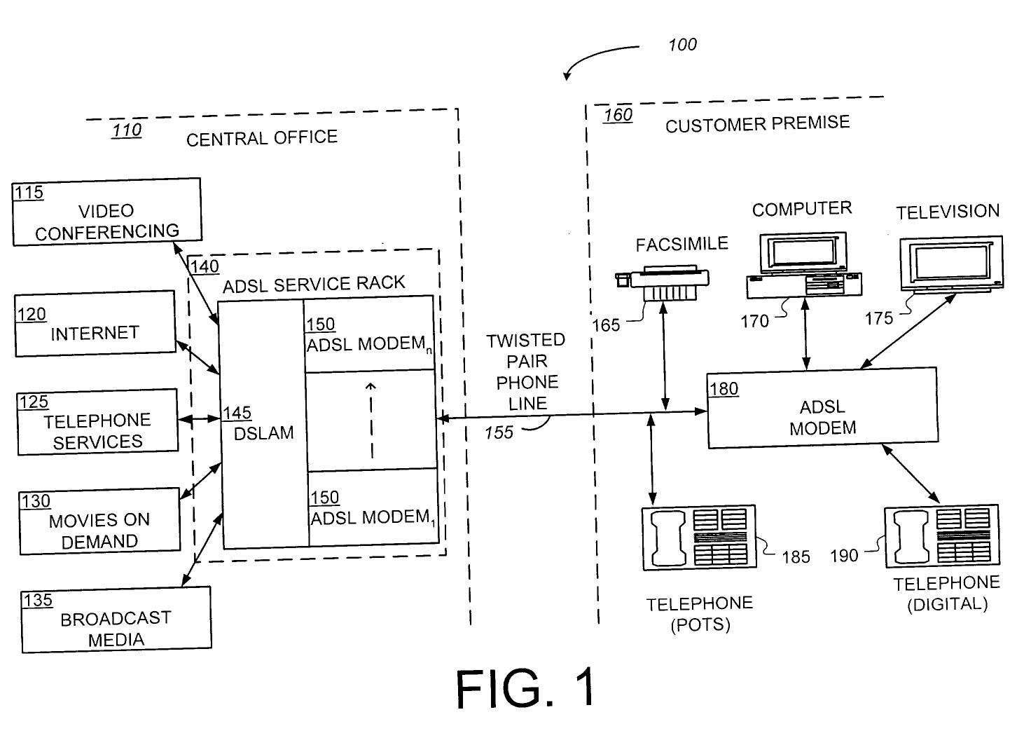

In a broad sense, the invention as embodied in FIGS. 1 through 9 provides systems and methods for improving digital subscriber line (DSL) performance. Conceptually, each of the embodiments maximizes performance by employing dual-modulation tuning during data transmission. In one example, a dual bit-mapping technique is employed so that one bit-mapping scheme is used when self-disturbance is present in the system and another bit-mapping scheme is used when self-disturbance is not present in the system. Thus, by using different bit-mapping schemes as a function of self-disturbance, greater efficiency can be achieved in data transmission.

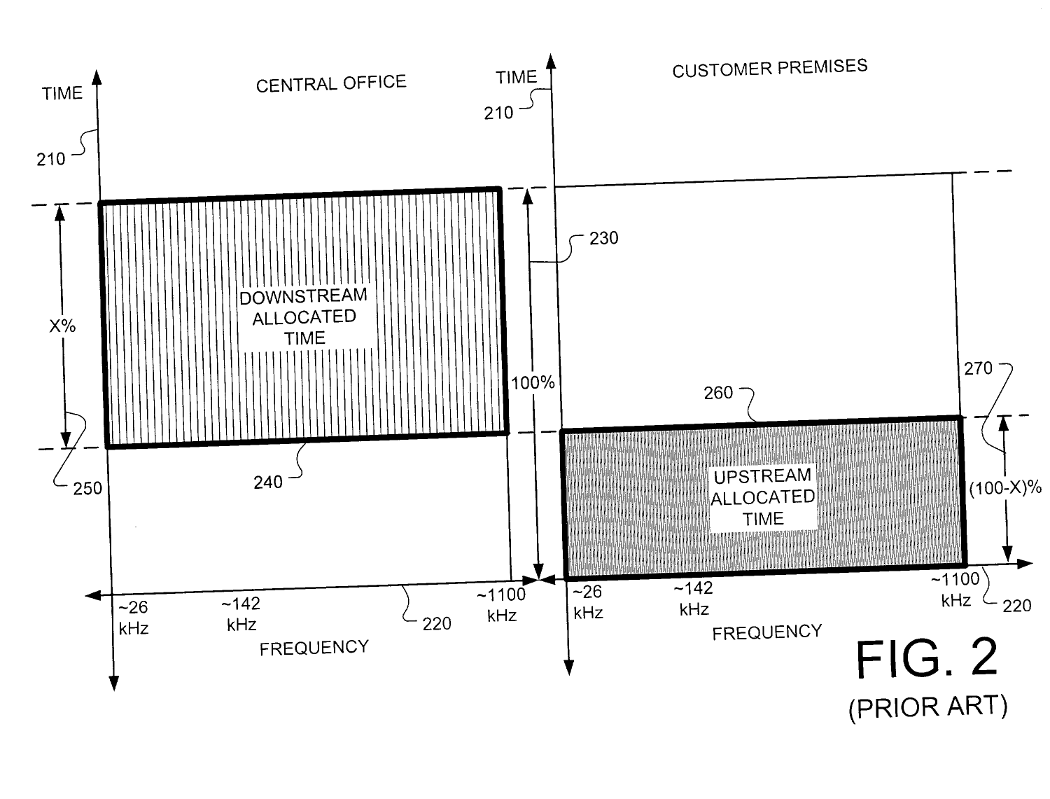

FIG. 1 is a block diagram showing a non-limiting example of a digital communication system as an asymmetric digital subscriber line (ADSL) system 100. In this non-limiting example environment, a central office 110 is connected to a customer premises 160 via a two-conductor pair wire 155. On the side of the central office 110 an ADSL service rack 140 gathers information for transmission. The information may be in the form of video conferencing 115, Internet 120, telephone services 125, movies on demand 130, or broadcast media 135. All of the information is gathered at a digital subscriber line access multiplexer (DSLAM) 145, which assembles the data for transmission by ADSL modems 150. Once the information has been coded and framed, it is sent to the customer premises 160 via a local loop, generally a two-conductor pair 155. The data is received at the customer premises 160 by an ADSL modem 180. The information is then decoded and provided to the user. Several non-limiting examples of communication services that use the decoded information include a fax 165, a user's computer 170, a television set 175, an analog telephone 185, or, in the alternative, a digital telephone 195. Typically, ADSL systems employ various techniques for transmitting both upstream and downstream signals. Three examples are shown in FIGS. 2 through 4. Unfortunately, given the sub-optimal system settings associated with the techniques of FIGS. 2 through 4, a different approach to transmitting data is desirable.

FIG. 2 is a graph showing an example of time-division multiplexing. Two graphs are shown in which a downstream allocated time 240 for a central office is shown on the left while an upstream allocated time 260 for a customer premises is shown in the right. The graphs show frequency plotted on the x-axis 220 and time plotted on the y-axis 210, with a total data transmission time (designated as 100%) 230 divided into a downstream portion 250 (designated as X %) (X is a variable parameter that is tuned according the constraints that are determined to maximize the transmission) and an upstream portion 270 (designated as (100-X)%). As shown in FIG. 2, a downstream signal is transmitted from the central office during the X % downstream portion 250 of the total time 230 using the entire ADSL bandwidth. During this time, no upstream signals are transmitted from the customer premises. Conversely, an upstream signal is transmitted from the customer premises during the (100-X)% upstream portion 270 of the total time 230 using the entire ADSL bandwidth. During this time, no downstream signals are transmitted. Thus, time-division multiplexing may be seen as utilizing two masks: (1) a downstream mask, which spans the entire ADSL frequency bandwidth but is only used for a portion of the total time; and (2) an upstream mask, which spans the entire ADSL frequency bandwidth but is only used for the remaining portion of the total time. As seen here, time-division multiplexing does not permit simultaneous transmission of both upstream and downstream signals, which, in turn, creates an inefficiency in data transmission. Since time-division multiplexing is know to those having ordinary skill in the art, further discussion of time-division multiplexing is omitted here.

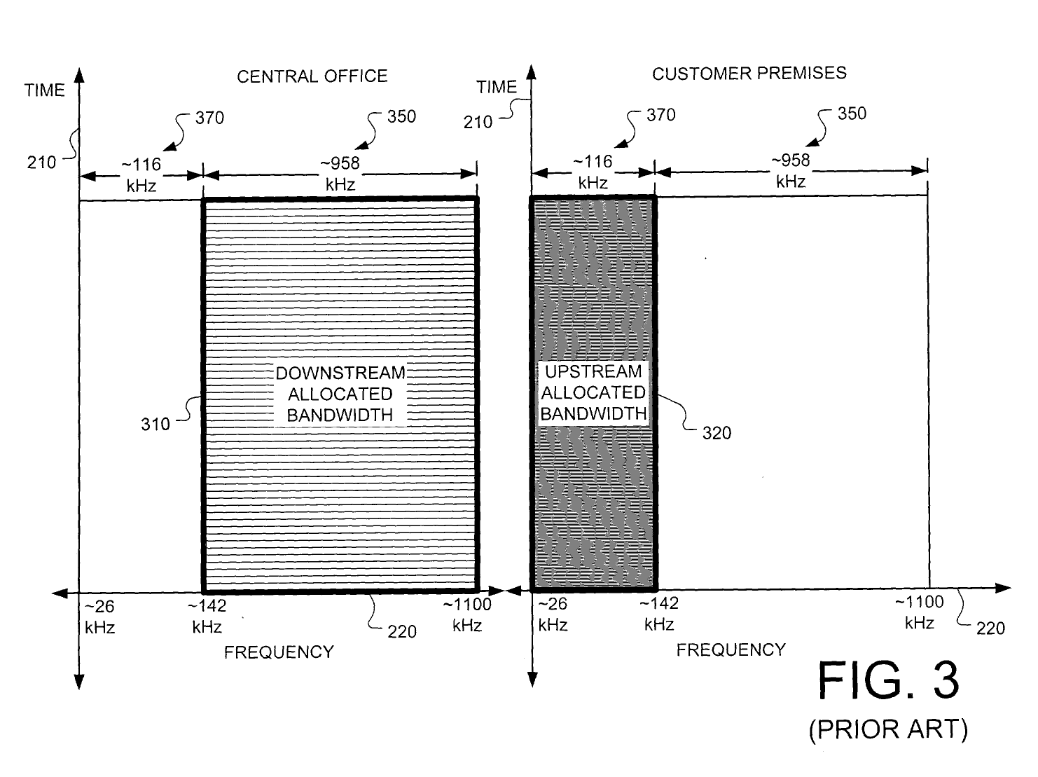

FIG. 3 is a graph showing an example of frequency-division multiplexing. Two graphs are shown in which a downstream-allocated bandwidth 310 for a central office is shown on the left while an upstream-allocated bandwidth 320 for a customer premises is shown in the right. The graphs show frequency plotted on the x-axis 220 and time plotted on the y-axis 210. In frequency-division multiplexing, a downstream signal is transmitted from a central office to a customer premises in a specific downstream frequency range 350, and an upstream signal is transmitted from a customer premises to a central office in a specific upstream frequency range 370. As shown in FIG. 3, the downstream-allocated bandwidth 310 and the upstream-allocated bandwidth 320 have no overlapping frequencies. Thus, unlike the time-division multiplexing of FIG. 2, both upstream and downstream signals in frequency-division multiplexing may be transmitted simultaneously. In this sense, frequency-division multiplexing may be seen as utilizing two masks: (1) a downstream mask, which spans a portion of the entire ADSL frequency bandwidth; and (2) an upstream mask, which spans a different portion of the entire ADSL frequency bandwidth. While the specific example of FIG. 3 shows the ADSL upstream bandwidth ranging from approximately 26 kHz to approximately 142 kHz and the ADSL downstream bandwidth ranging from approximately 142 kHz to approximately 1100 kHz, the principle of frequency-division multiplexing (i.e., using non-overlapping bandwidths for upstream and downstream signal transmission) is not limited to the specified frequency ranges, but may encompass any system utilizing non-overlapping bandwidths for upstream and downstream signal transmission. As shown in FIG. 3, only a portion of the entire ADSL bandwidth is used as the downstream-allocated bandwidth 310. Thus, when there are no upstream signals, the upstream-allocated bandwidth is unused, thereby creating an inefficiency. Since frequency-division multiplexing is know to those having ordinary skill in the art, further discussion of frequency-division multiplexing is omitted here.

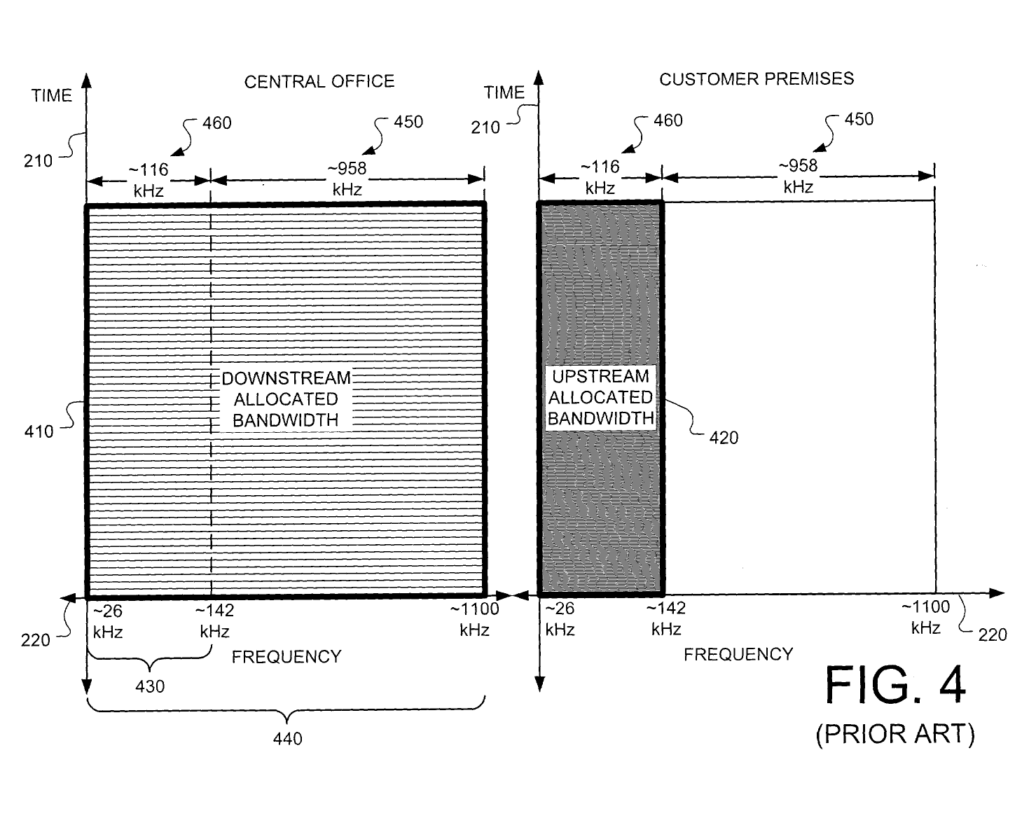

FIG. 4 is a graph showing full-bandwidth overlap of upstream and downstream signals in a particular frequency range for an ADSL modem operating in an echo-cancellation mode when self-disturbance effects are present. Two graphs are shown in which a downstream-allocated bandwidth 410 for a central office is shown on the left while an upstream-allocated bandwidth 420 for a customer premises is shown on the right. The graphs show frequency plotted on the x-axis 220 and time plotted on the y-axis 210. As shown in FIG. 4, when echo-cancellation is used to reduce self-disturbance effects such as echoes or near-end cross-talk (NEXT), a downstream signal may be transmitted from a central office to a customer premises using the entire frequency bandwidth 440 at all times. Since an upstream signal is transmitted from a customer premises to a central office in a specific upstream frequency range 460, the downstream signal 410 and the upstream signal 420 overlap within that frequency range 460 if both upstream and downstream signals are transmitted concurrently. This type of overlap results in self-disturbance effects (e.g., echoes and self-NEXT), which consequently result in signal degradation. In order to reduce the signal degradation, complex echo-cancellation techniques may be used to reduce the self-disturbance. Unfortunately, echo-cancellation techniques typically employ a single-modulation tuning within the overlapping bandwidth. In other words, the data-loading (or bit-loading) scheme is uniform regardless of whether or not upstream signals are being transmitted. Thus, when no upstream signals are present, the uniform data-loading scheme results in unused capacity, which results in inefficient data transmission. Since echo-cancellation techniques are known to those of skill in the art, further discussion of echo-cancellation techniques is omitted here.

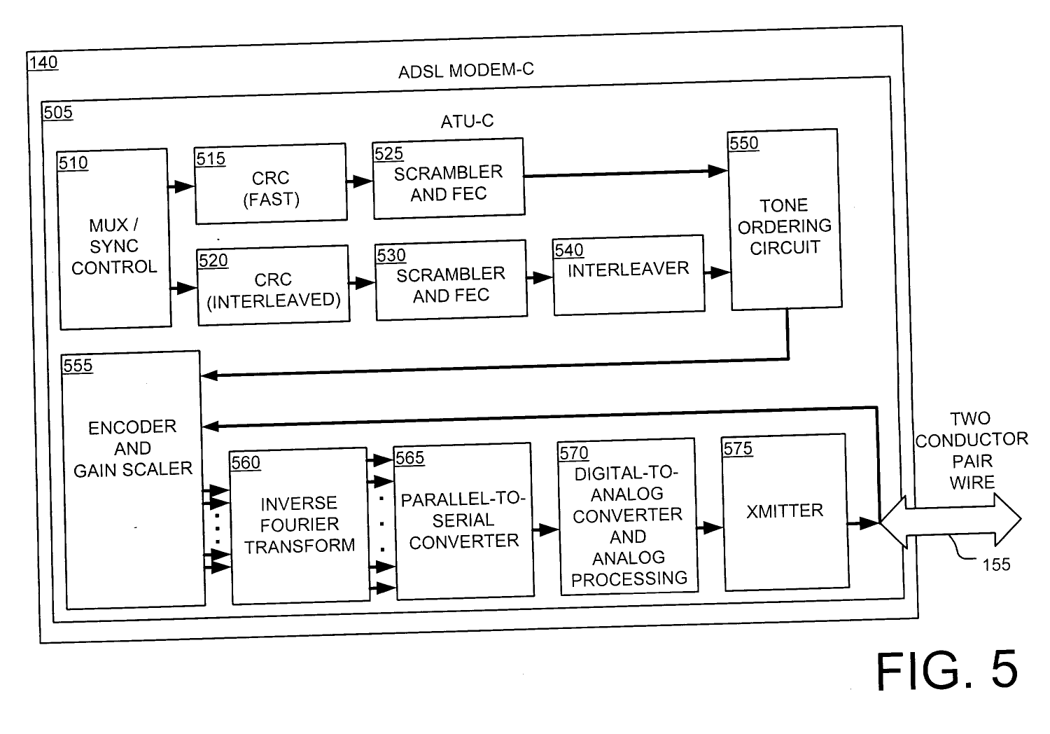

FIGS. 5 through 9 show several embodiments of the invention, which show dual-modulation tuning in systems that exhibit self-disturbance effects. The dual-modulation tuning schemes, shown in the several embodiments of FIGS. 5 through 9, permit greater data capacity as compared to conventional techniques.

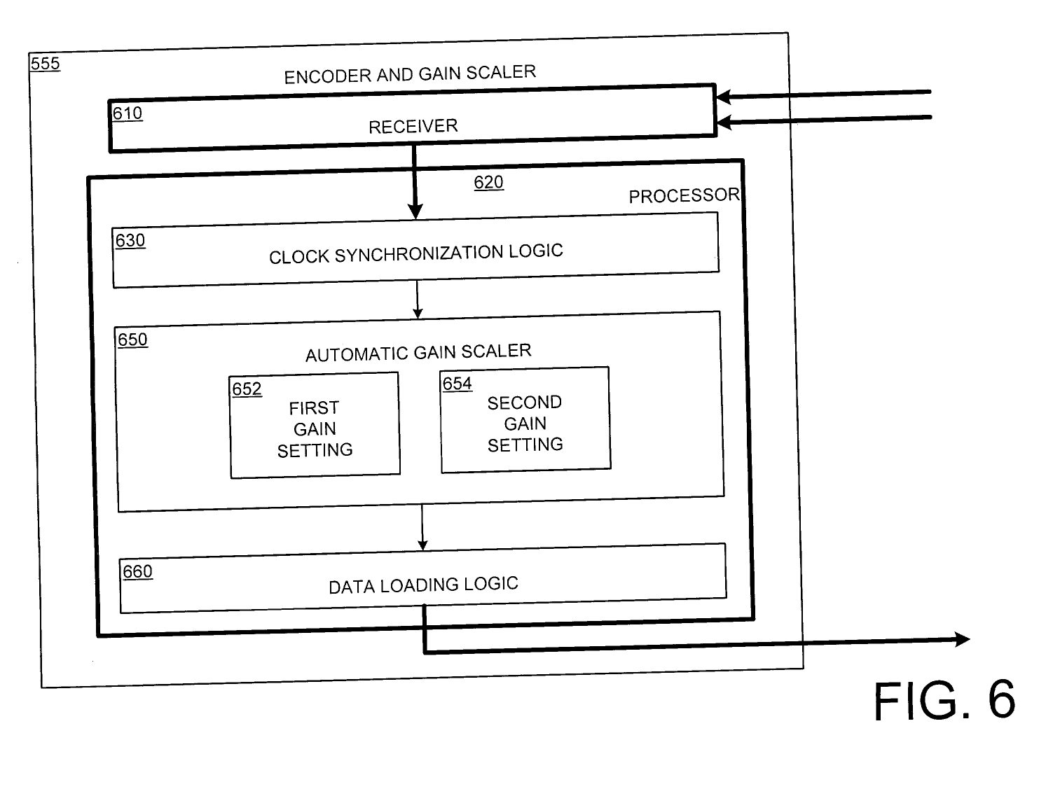

FIG. 5 is a block diagram showing the ADSL modem 150 of FIG. 1 in greater detail. While FIG. 5 shows only one ADSL modem 150, it should be appreciated that each of the ADSL modems 150 of FIG. 5 may have similar components. As shown in FIG. 5, the ADSL modem 150 at the central office 110 comprises an ADSL transceiver unit (ATU-C) 505 configured to assemble data for transmission on the communication line 155. In this regard, the ATU-C 505 comprises both a fast path and an interleaved path between a multiplexer (MUX) and synchronization (sync) control block 510 and a tone ordering circuit 550. The fast path, which provides low latency, comprises a fast cyclic redundancy checking (CRC) block 515 and a scrambling and forward error correcting (FEC) block 525. The interleaved path, which provides a lower error rate at a greater latency, comprises an interleaved CRC block 520, a scrambling and FEC block 530, and an interleaver 540. Since MUX/sync control blocks 510, CRC blocks 515, 520, scrambling and FEC blocks 525, 530, interleavers 540, and tone ordering circuits 550 are known to those of ordinary skill in the art, further discussion of these components is omitted here. However, it should be appreciated that the signal, upon traversing either the fast path or the interleaved path, enters an encoding and gain scaling block 555, which encodes the data into a constellation and also scales the data for transmission. The encoding and gain scaling block 555 is discussed in greater detail with reference to FIG. 6.

Once the data has been encoded and gain-scaled, the data is relayed in parallel blocks to an inverse Fourier transform (IFT) block 560, which performs a IFT on the parallel data blocks. The IFT data is conveyed to a parallel-to-serial (P/S) converter 565, which converts the data into a serial data stream. The serial data stream is conveyed to a digital-to-analog (D/A) converter and analog processor 570, which produces an analog signal for data transmission. Since IFT blocks 550, P/S converters 555, D/A converters and analog processors 570 are known to those of ordinary skill in the art, further discussion of these components is omitted here. The analog signal is transmitted through the communication line 155 by a transmitter 575 in the ATU-C 505.

FIG. 6 is a block diagram showing the encoder and gain scaler 555 of FIG. 5 in greater detail. As shown in FIG. 6, the encoder and gain scaler 555 comprises a receiver 610 and a processor 620. In an example embodiment, the receiver 610 and the processor 620 are part of a DSL system employing DMT modulation. Additionally, if the DSL-DMT system is governed by cyclostationary interferences from concurrently deployed systems, such as Time-Compression Multiplexed (TCM) integrated Services Digital Network (ISDN), then the DSL system may also be capable of dual-modulation tuning (e.g., dual bit-mapping). Since dual bit-mapping techniques are known to those of ordinary skill in the art and are also discussed in greater detail in the above-referenced related applications, further discussion of dual bit-mapping techniques is omitted here. In any event, in the example embodiment, the receiver 610 receives data from the tone-ordering circuit 550 as well as signals from the communication line 155. Since upstream and downstream signals are impacted by the cyclostationary nature of the TCM-ISDN interferences, the signals from the communication line 155 also comprise information related to an external clock that is synchronized to the cyclostationary interferences. The external clock indicates whether or not self-disturbance is present in the system because the external clock signal indicates whether or not the cyclostationary interference is “on” or “off.” In other words, information related to the external clock signal further provides information on whether or not the upstream and downstream signals overlap. The signals from the communication line 155 are updated for each data frame being encoded and gain scaled. Thus, the encoder/gain scaler 555 is continuously updated with information on which mode (i.e., overlap or non-overlap) is being used at any given time.

For the dual-modulation tuning system in the example embodiment, the processor 620 is configured to receive the signal from the receiver 610 and select an appropriate gain setting as a function of the external clock signal. In this regard, the processor 620 comprises clock-synchronization logic 630, an automatic gain scaler 650, and data-loading logic 660. The clock-synchronization logic 630 is adapted to receive the signal from the receiver 610 and extract the external clock signal. Since techniques for extracting clock signals from line signals is known in the art, further discussion of such techniques is omitted here. The external clock signal is indicative of whether the cyclostationary noise is “on” or “off.” In other words, the clock-synchronization logic 630 is adapted to determine whether or not self-disturbance effects are present from the external clock signal. The automatic gain scaler 650 receives the external clock signal from the clock-synchronization logic 630 and selects a first (preferably higher) gain setting 652 if the cyclostationary noise is “off.” Conversely, the automatic gain scaler 650 selects a second (preferably lower) gain setting 654 if the cyclostationary noise is “on.” In this regard, if the external clock signal indicates that the cyclostationary noise is “off,” then the automatic gain scaler 650 sets the gain for non-overlap mode (or a first bit-mapping scheme). If the external clock signal indicates that the cyclostationary noise is “on,” then the automatic gain scaler 650 sets the gain for overlap mode (or a second bit-mapping scheme). Thus, greater efficiencies may be achieved by employing this type of dual bit-mapping technique. More generally, the automatic gain scaler 650 sets system parameters to one of two data-transmission modes depending on whether or not self-disturbance effects are present.

The processor 620 also comprises data loading logic 660, which loads each of the sub-carriers. In an example embodiment, once the automatic gain scaler 650 determines the appropriate gain setting 652, 654, the data loading logic 660 loads the sub-carriers with data according to the determined gain setting 652, 654. Thus, the data is loaded to each sub-carrier using an optimized power level. Since data-loading techniques are known in the art and are also described in the above-referenced related applications, further discussion of data-loading is omitted here.

In another embodiment, signal-to-noise ratios (SNR) of the line may be used to determine the gain setting rather than using external clock signals. In this regard, the system may be configured to select one of the dual-modulation tuning schemes for overlap and non-overlap modes by evaluating the SNR of the communication line 155. For example, since the self-disturbance effects are much greater during overlap mode, the received signal may have a lower SNR during overlap mode. Conversely, the received signal may have a higher SNR during non-overlap mode because self-disturbance effects are attenuated during non-overlap mode. In this regard, it should be appreciated by those having skill in the art that the processor 620 may select the gain settings 652, 654 as a function of SNR, rather than as a function of an external clock signal.

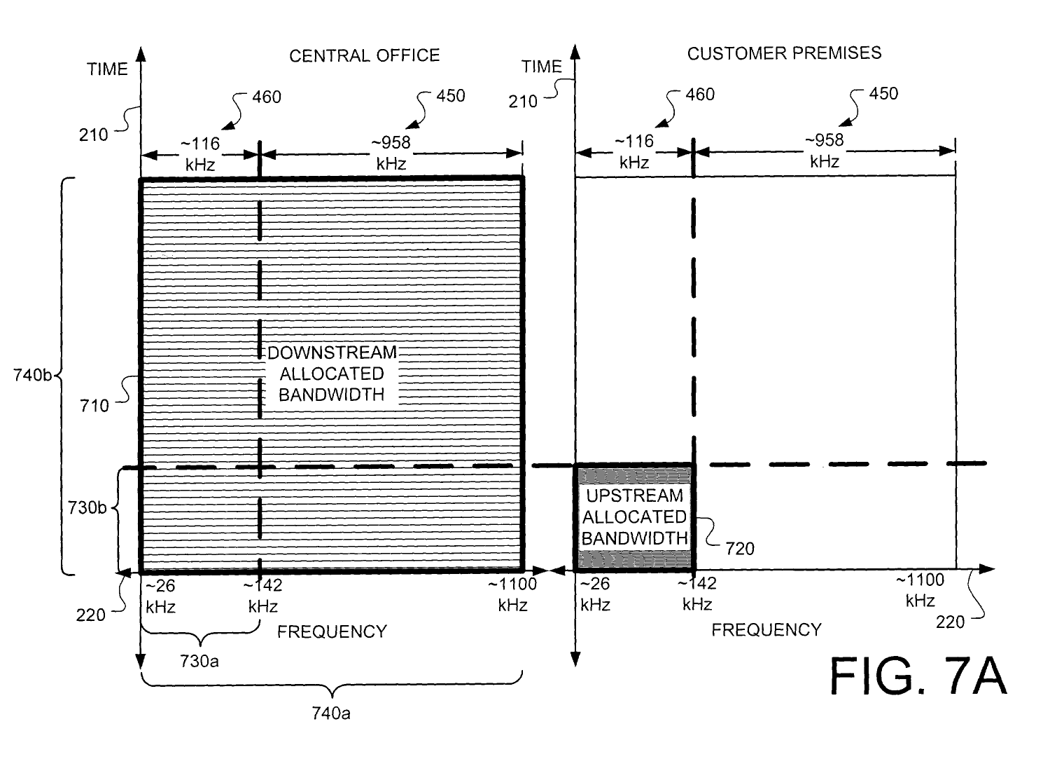

Having described several embodiments of systems configured to employ dual-modulation tuning in the presence of self disturbance, attention is turned to FIGS. 7A and 7B, which are graphs in the time-frequency plane showing the loading of data using a dual-modulation tuning scheme.

FIG. 7A is a graph showing partial-bandwidth overlap of upstream and downstream signals in a particular frequency range for an ADSL modem exhibiting self-disturbance effects. FIG. 7B is a graph showing dual bit-mapping of data for systems exhibiting self-disturbance effects when there is a partial-bandwidth overlap of upstream and downstream signals. Two graphs are shown in each of FIGS. 7A and 7B, in which a downstream-allocated bandwidth 710 for a central office is shown on the left while an upstream-allocated bandwidth 720 for a customer premises is shown on the right. The graphs show frequency plotted on the x-axis 220 and time plotted on the y-axis 210. As shown in FIG. 7A, the upstream-allocated bandwidth 720 overlaps with a portion 730a of the downstream-allocated bandwidth 710 during a portion of the time 730b.

As shown in FIG. 7B, a first bit-loading scheme is used for data transmission during the portion of the time 730b in which the upstream-allocated bandwidth 720 and the downstream-allocated bandwidth 710 overlap. Conversely, a second bit-mapping scheme is used for data transmission when the upstream-allocated bandwidth 720 and the downstream-allocated bandwidth 710 do not overlap. Stated differently, a first set of system parameters is used when self-disturbance is present in the system, and a second set of system parameters is used when self-disturbance is not present in the system. In this regard, by using a dual-modulation tuning scheme, greater data capacity may be achieved.

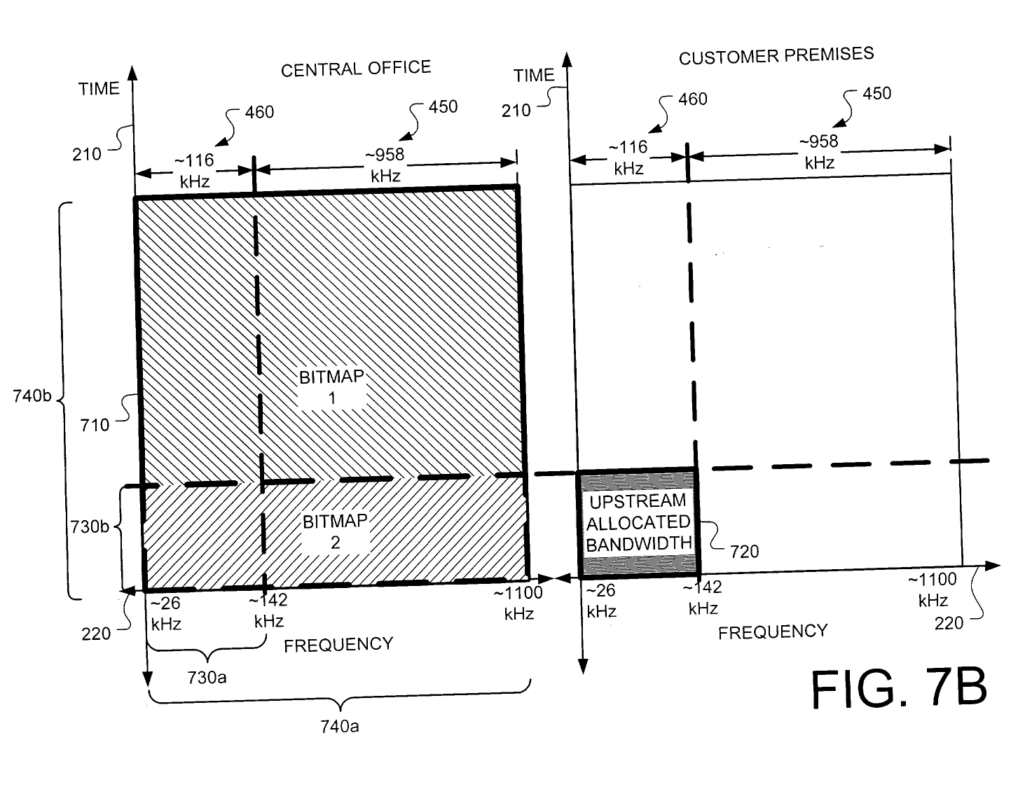

FIG. 8 is a flowchart showing one embodiment of a method that employs dual-modulation tuning in systems that exhibit self-disturbance effects. As shown in FIG. 8, one embodiment of the method begins when the system determines (820) whether or not self-disturbance is present. In one embodiment, the presence or absence of self-disturbance is determined (820) for a DSL system employing DMT modulation and capable of employing a dual bit-mapping technique.

If the system determines (820) that self-disturbance is not present, then the system sets (830) its system parameters to a first data-transmission mode. In one embodiment, the first data-transmission mode is a first bit-mapping scheme in a dual bit-mapping technique. Once the system sets (830) its system parameters to the first data-transmission mode, the system further detennines (850) whether or not data transmission has ended. If it is determined that the data transmission has not ended, then the process again determines (820) whether or not self-disturbance is present. If, on the other hand, it is determined (850) that the data transmission has ended, then the process ends (890).

If the system determines (820) that self-disturbance is present, then the system sets (840) its system parameters to a second data-transmission mode. In an example embodiment, the second data-transmission mode is a second bit-mapping scheme in a dual bit-mapping technique. Once the system sets (840) its system parameters to the second data-transmission mode, the system further determines (850) whether or not data transmission has ended. If it is determined that the data transmission has not ended, then the process again determines (820) whether or not self-disturbance is present. If, on the other hand, it is determined (850) that the data transmission has ended, then the process ends (890).

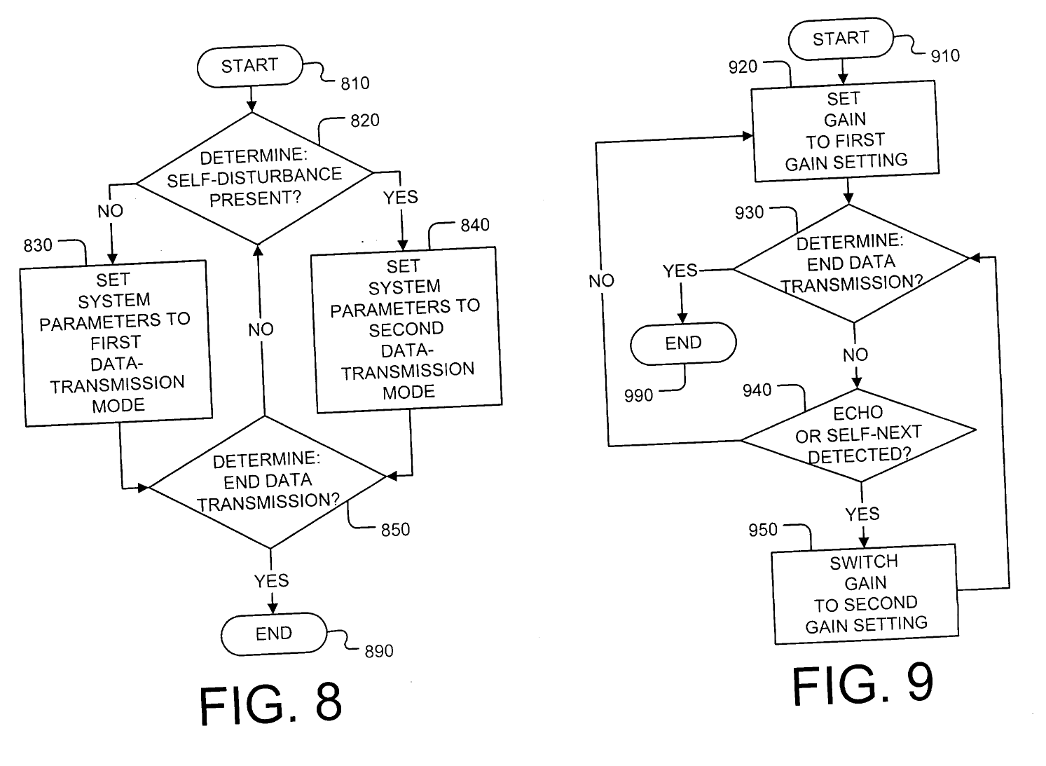

FIG. 9 is a flowchart showing another embodiment of a method that employs dual-modulation tuning in systems that exhibit self-disturbance effects. As shown in FIG. 9, one embodiment of the process begins by setting (920) a system gain to a first gain setting. The first gain setting may correspond to a first bit-mapping scheme in a dual-bit-mapping technique. Upon setting (920) the system gain to the first gain setting, the system determines (930) whether or not data transmission has ended. If it is determined (930) that data transmission has ended, then the process terminates (990). If, on the other hand, it is determined (930) that data transmission has not ended, then the system further determines (940) whether or not self-NEXT or echoes have been detected. If it is determined (940) that self-NEXT or echoes have not been detected, then the process repeats by setting (920) the system gain of the system to the first gain setting.

If, on the other hand, it is determined (940) that self-NEXT or echoes have been detected, then the system switches (950) the system gain from the first gain setting to a second gain setting. The second gain setting may correspond to a second bit-mapping scheme in a dual bit-mapping technique. Upon switching (950) to the second gain setting, the system determines (930) whether or not data transmission has ended. If it is determined (930) that data transmission has ended, then the process terminates (990). If, on the other hand, it is determined (930) that data transmission has not ended, then the process repeats by, again, determining (940) whether or not self-NEXT or echoes have been detected.

As shown in FIGS. 5 through 9, greater efficiency may be achieved by employing a dual-modulation tuning scheme or a dual bit-mapping technique and increasing data capacity in systems that exhibit self-disturbance.

The components in the ATU-C 505, the clock-synchronization logic 630, the automatic gain scaler 650, and the data-loading logic 660 described above may be implemented in hardware, software, firmware, or a combination thereof. In the preferred embodiment(s), the components in the ATU-C 505, the clock-synchronization logic 630, the automatic gain scaler 650, and the data-loading logic 660 are implemented in hardware using any or a combination of the following technologies, which are all well known in the art: a discrete logic circuit(s) having logic gates for implementing logic functions upon data signals, an application specific integrated circuit (ASIC) having appropriate combinational logic gates, a programmable gate array(s) (PGA), a field programmable gate array (FPGA), etc. In an alternative embodiment, the components in the ATU-C 505, the clock-synchronization logic 630, the automatic gain scaler 650, and the data-loading logic 660 are implemented in software or firmware that is stored in a memory and that is executed by a suitable instruction execution system.

Any process descriptions or blocks in flow charts should be understood as representing modules, segments, or portions of code which include one or more executable instructions for implementing specific logical functions or steps in the process, and alternate implementations are included within the scope of the preferred embodiment of the present invention in which functions may be executed out of order from that shown or discussed, including substantially concurrently or in reverse order, depending on the functionality involved, as would be understood by those reasonably skilled in the art of the present invention.

Although exemplary embodiments have been shown and described, it will be clear to those of ordinary skill in the art that a number of changes, modifications, or alterations may be made, none of which depart from the spirit of the present invention. For example, while echoes and self-NEXT have been described as examples of self-disturbance, it should be appreciated that other forms of self-disturbance may be ameliorated by the above-described systems and methods. Additionally, while dual bit-mapping techniques have been described as examples of dual-modulation tuning schemes, it should be appreciated that other data-loading schemes may be used as long as the data-loading scheme used in the presence of self-disturbance effects is different from the data-loading scheme used in the absence of self-disturbance effects. Additionally, while the example embodiments above show that the processor is a component part of the automatic gain scaler, it should be appreciated that a general-purpose processor may be used for the various functions of the ATU-C, in which case the automatic gain scaler would be a component part of the general-purpose processor. Additionally, while the example embodiments show dual-modulation tuning schemes in the context of ADSL systems employing DMT modulation, it should be appreciated that the above-described systems and methods are readily applicable to any communication system exhibiting self-disturbance effects. All such changes, modifications, and alterations should therefore be seen as within the scope of the present invention.

The claims are:

1. A communication method comprising:
determining a presence of self-disturbance in a system, the system being capable of at least two data-transmission modes; and
setting system parameters to a first data-transmission mode in response to determining that the self-disturbance is not present in the system.

2. The method of claim 1, wherein the determining the presence of self-disturbance in a system comprises determining a presence of the self-disturbance in digital subscriber line (DSL) system configured for discrete multi-tone (DMT) modulation, the DSL system further being configured for dual bit-mapping of data.

3. The method of claim 1, further comprising setting the system parameters to a second data-transmission mode in response to determining that the self-disturbance is present in the system.

4. The method of claim 3, wherein the setting the system parameters to the first data-transmission mode comprises establishing a first gain setting in response to determining that the self-disturbance is not present in the system.

5. The method of claim 4, wherein the setting the system parameters to the second data-transmission mode comprises switching from the first gain setting to a second gain setting in response to determining that the self-disturbance is present in the system, the second gain setting being different from the first gain setting.

6. The method of claim 5, wherein the establishing the first gain setting comprises establishing a gain setting for each bin in a digital subscriber line (DSL) system employing discrete multi-tone (DMT) modulation.

7. The method of claim 5, wherein the switching from the first gain setting to the second gain setting comprises switching a gain setting for at least one bin in a digital subscriber line (DSL) system employing discrete multi-tone (DMT) modulation.

8. The method of claim 1, wherein the determining the presence of self-disturbance comprises detecting an echo.

9. The method of claim 8, further comprising setting the system parameters to the first data-transmission mode in response to detecting the echo.

10. The method of claim 1, wherein the determining the presence of self-disturbance comprises detecting near-end cross-talk (NEXT).

11. The method of claim 10, further comprising setting the system parameters to the first data-transmission mode in response to detecting the NEXT.

12. In a digital subscriber line (DSL) modem employing discrete multi-tone (DMT) modulation, a processor comprising:
logic adapted to determine a presence of self-disturbance in the communication system; and
logic adapted to set system parameters to a first data-transmission mode in response to determining that the self-disturbance is not present in the communication system.

13. A communication system capable of at least two data-transmission modes, the communication system comprising:
a processor adapted to determine a presence of self-disturbance in the communication system, the processor being further adapted to set system parameters to a first data-transmission mode in response to determining that the self-disturbance is not present in the communication system; and
a transmitter adapted to transmit data using the system parameters set by the processor.

14. The system of claim 13, wherein the processor is further adapted to set the system parameters to a second data-transmission mode in response to determining that the self-disturbance is present in the communication system.

15. The system of claim 14, further comprising a gain scaler adapted to establish a first gain setting in response to determining that the self-disturbance is not present in the communication system.

16. The system of claim 15, wherein the gain scaler is further adapted to establish a second gain setting in response to determining that the self-disturbance is present in the communication system, the second gain setting being different from the first gain setting.

17. A communication system capable of at least two data-transmission modes, the communication system comprising:
means for determining a presence of self-disturbance in the communication system; and
means for setting system parameters to a first data-transmission mode in response to determining that the self-disturbance is not present in the communication system.

18. The system of claim 17, further comprising means for setting the system parameters to a second data-transmission mode in response to determining that the self-disturbance is present in the communication system.

19. The system of claim 18, further comprising means for establishing a first gain setting in response to determining that the self-disturbance is not present in the communication system.

20. The system of claim 19, further comprising means for switching from the first gain setting to a second gain setting in response to determining that the self-disturbance is present in the communication system, the second gain setting being different from the first gain setting.
